(19) United States
(12) Patent Application Publication
(10) Pub. No.: US 2014/0246664 A1
(43) Pub. Date: Sep. 4, 2014

(54) ORGANIC ELECTROLUMINESCENCE DISPLAY PANEL AND MANUFACTURING METHOD THEREFOR

(71) Applicant: Ryo Shoda, Taito-ku (JP)

(72) Inventor: Ryo Shoda, Taito-ku (JP)

(73) Assignee: Toppan Printing Co., Ltd.

(21) Appl. No.: 14/350,101

(22) PCT Filed: Sep. 14, 2012
(86) PCT No.: PCT/JP2012/005919

§ 371 Date: Apr. 7, 2014

(30) Foreign Application Priority Data
Oct. 18, 2011 (JP) 2011-228626 2011

(51) Int. Cl. H01L 51/52; H01L 51/50; H01L 27/32

(52) U.S. Cl. CPC H01L 51/5203; H01L 27/3244; H01L 51/5012
USPC 257/40; 438/34

(57) ABSTRACT

To provide a transparent organic EL display panel that does not impair transparency while light is not emitted, the transparent organic electroluminescence display panel is provided with first transparent electrodes formed on a transparent substrate, a transmittance-adjusting layer formed on the transparent substrate and away from the first transparent electrodes, a partition wall formed on the transparent substrate and the transmittance-adjusting layer so as to partition the first transparent electrodes, a light-emitting medium layer formed on the first transparent electrodes and including at least an organic light-emitting layer, and a second transparent electrode formed on the light-emitting medium layer.

### TECHNICAL FIELD

The present invention relates to an organic electroluminescence display panel and a manufacturing method therefor.

### BACKGROUND ART

An organic electroluminescence element (hereinafter, organic EL element) is provided with an organic light-emitting layer made of an organic light-emitting material between two opposing electrodes, and, when voltage is applied between both electrodes, holes and electrons are injected from the positive electrode and the negative electrode respectively, a current is made to flow in the organic light-emitting layer, and the holes and the electrons recombine in the organic light-emitting layer, whereby the organic EL element emits light.

Generally, a sheet on which patterned photosensitive polyimide is formed in a partition wall shape so as to partition light-emitting pixels is used as a substrate for a display panel. At this time, the partition wall pattern is formed so as to cover an edge section of a transparent electrode formed as the positive electrode.

In addition to the organic light-emitting layer, a carrier injection layer (also referred to as carrier transportation layer) is formed between the electrodes. The carrier injection layer is a layer used to control the injection amount of electrons when injecting electrons into the organic light-emitting layer from one electrode or to control the injection amount of holes when injecting holes into the organic light-emitting layer from the other electrode, and refers to a layer inserted between the electrode and the organic light-emitting layer. An electron-transporting organic compound such as a metallic complex of a quinolinol derivative or, for example, an alkali metal having a relatively small work function such as Ca or Ba is used for the electron injection layer, and there is a case where a plurality of layers having the above-described function is laminated. A triphenylamine-based derivative (TPD) (refer to PTL 1), a mixture of polythiophene and polystyrene sulfonic acid (PEDOT:PSS) (refer to PTL 2) or a hole transportation material of an inorganic material (refer to PTL 3) are known as the hole injection layer. Any of the above-described layers is inserted between the electrode and the light-emitting layer to improve the light-emitting efficiency by controlling the injection amounts of electrons and holes, and is essential to obtain a high-performance organic EL display panel.

Next, as a method for forming the hole injection layer used to inject hole carriers, there are two methods, that is, dry film formation and a wet film-forming method. In a case where the wet film-forming method is used, generally, a polythiophene derivative dispersed in water is used, but an aqueous ink is easily affected by a substrate, and is extremely difficult to be uniformly applied. On the contrary, in the dry film formation, the entire surface can be conveniently and uniformly coated.

Similarly, there are also two methods as a method for forming the organic light-emitting layer, that is, dry film formation and a wet film-forming method. In a case where a vacuum deposition method that is dry film formation capable of easily forming a uniform film is used, it is necessary to conduct patterning using a fine pattern mask, and patterning of the preparation of a large substrate or fine patterning is extremely difficult.

Therefore, in recent years, an attempt has been made to procure a method in which a coating fluid is prepared by dissolving a macromolecular material in a solvent and a thin film is formed using the above-described coating fluid and the wet film-forming method. In a case where a light-emitting medium layer including the organic light-emitting layer is formed using the coating fluid of a macromolecular material and the wet film-forming method, an ordinary layer structure is a three-layer structure in which a hole injection layer, an interlayer or a hole transportation layer, and an organic light-emitting layer are laminated from the positive electrode side. At this time, it is possible to coat the organic light-emitting layer separately using organic light-emitting inks obtained by dissolving or stably dispersing in a solvent organic light-emitting materials emitting light of individual colors of red (R), green (G) and blue (B) to make the organic light-emitting layer into a color panel (refer to PTL 4 and 5).

When the wet film formation is used, a large substrate or a fine pattern can be easily prepared without using a fine pattern mask.

Ideally, it is possible to improve the performance by using separate carrier injection layers for light-emitting layers of individual colors of RGB; however, since using separate carrier injection layers increase the number of steps in mass production process and it is difficult to prepare a high-precision pattern, it is normal to form a common solid film for RGB as the carrier injection layer.

Meanwhile, the above-described organic EL element is characterized by the extremely thin thickness of the element, and a study is underway to produce a so-called double-sided light-emitting transparent organic EL element using the above-described characteristic. A display employing the above-described characteristic is characterized in that the display remains transparent while light is not emitted and emits light when electrically conducted, and is attracting attention as an in-vehicle monitor or a display panel having a characteristic of transparency for commercial, watches, lighting and televisions. For example, a color display device is introduced in PTL 6 in which transparent EL elements for three colors of RGB are overlapped.

As described above, while the light-emitting performance is important in a transparent organic EL element, there is another demand for transparency while not emitting light, that is, a demand for large and constant in-plane transmittance. Particularly, a TFT that is a switching element, a metallic composite oxide that is an extraction wire for a positive electrode or a positive electrode used in an organic EL element such as indium tin composite oxide (ITO), indium zinc composite oxide or zinc aluminum composite oxide, and the like have a large refractive index and have a huge influence on transparency.

In PTL 7, an effect that modulates light with a specific wavelength using the interference of reflected light on a glass/transparent electrode interface is used; however, conversely speaking, this means that a difference in wavelength dispersion of transmittance is caused between a transparent electrode-absent region and a transparent electrode-present region, wires appear when light is not emitted, and the transparency is poor.

In addition, PTL 8 discloses a method for effectively extracting white light by adjusting the refractive index or film thickness of the positive electrode and the refractive index or film thickness of the organic layer; however, at the same time, the difference in wavelength dispersion of transmittance while light is not emitted becomes great.

As described above, even in all the features of the related art, there was a problem in that, when light was not emitted, positive electrode wires appeared, and the transparency was poor.

### CITATION LIST

### Patent Literatures

PTL 1: JP 2001-93668 A
PTL 2: JP 2001-155858 A
PTL 3: JP 2916098 B
PTL 4: JP 2851185 B
PTL 5: JP 9-63771 A
PTL 6: JP 2007-157487 A
PTL 7: JP 7-240277 A
PTL 8: JP 2004-79421 A

### SUMMARY OF INVENTION

### Technical Problem

An object of the invention is to provide a transparent organic EL display panel that does not impair transparency while light is not emitted.

### Solution to Problem

The invention has been made to solve the above-described problems, and according to a first aspect of the invention, there is provided a transparent organic electroluminescence display panel including first transparent electrodes formed on a transparent substrate, a transmittance-adjusting layer formed on the transparent substrate and away from the first transparent electrodes, a partition wall formed on the transparent substrate and the transmittance-adjusting layer so as to partition the first transparent electrodes, a light-emitting medium layer formed on the first transparent electrodes and including at least an organic light-emitting layer, and a second transparent electrode formed on the light-emitting medium layer.

In addition, according to a second aspect of the invention, there is provided the transparent organic electroluminescence display panel of the first aspect, in which the transmittance-adjusting layer is made of the same material as for the first transparent electrodes.

In addition, according to a third aspect of the invention, there is provided the transparent organic electroluminescence display panel of the first or second aspect, in which the first transparent electrodes and the transmittance-adjusting layer are formed away from each other, a gap between the first transparent electrode and the transmittance-adjusting layer is in a range of 1 μm to 50 μm.

In addition, according to a fourth aspect of the invention, there is provided a manufacturing method for the transparent organic electroluminescence display panel according to any one of the first to third aspects, in which the first transparent electrodes and the transmittance-adjusting layer are formed at the same time.

### Advantageous Effects of Invention

It becomes possible to provide a transparent organic EL display panel that does not impair the transparency while light is not emitted.

### BRIEF DESCRIPTION OF DRAWINGS

FIG. 1 is a schematic explanatory plan view of an example of a transparent organic EL display panel of the invention;

FIG. 2 is a schematic explanatory cross-sectional view of the example of the transparent organic EL display panel of the invention; and

FIG. 3 is a schematic view of a typography apparatus.

### DESCRIPTION OF EMBODIMENTS

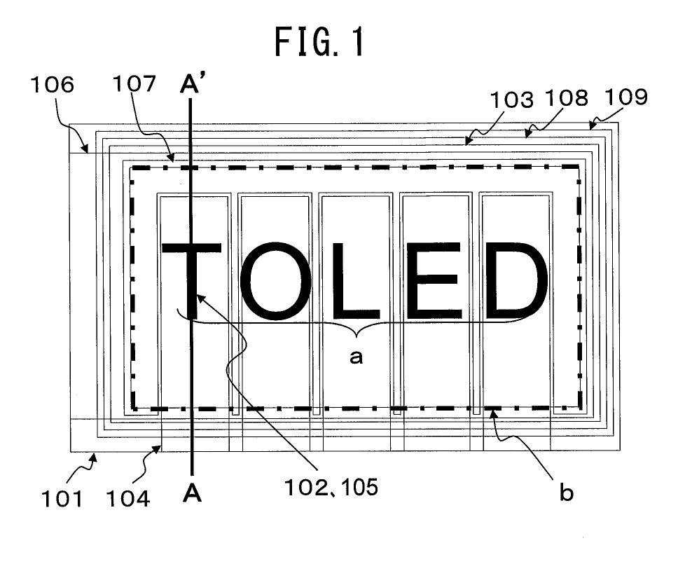

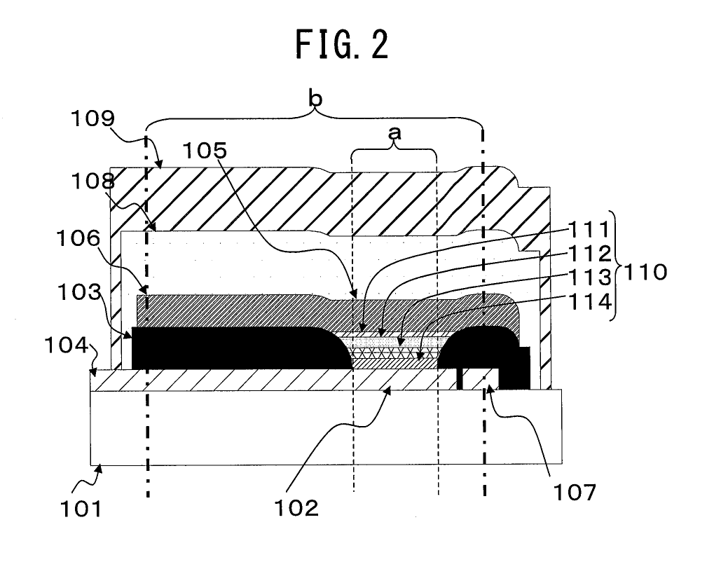

A schematic plan view of a passive matrix drive-type organic EL display panel was illustrated in FIG. 1 as a first aspect of the invention, and a schematic cross-sectional view of the organic EL display panel taken along AA′ in FIG. 1 was illustrated in FIG. 2. The organic EL display panel of the invention includes first transparent electrodes 102 formed on a transparent substrate 101 as positive electrodes, a second transparent electrode 105 formed opposite to the first transparent electrodes as a negative electrode, and a layer (light-emitting medium layer 110) sandwiched therebetween.

The first transparent electrodes 102 are formed as pixel electrodes in pixel areas a in which pixels are partitioned using a partition wall 103, and a second transparent electrode 105 is formed as an opposite electrode above the pixel areas. The light-emitting medium layer includes at least an organic light-emitting layer 113 contributing to light emission, a hole injection layer 111 as a carrier injection layer injecting holes, a hole transportation layer 112 as a carrier injection layer transporting holes, and an electron injection layer 114 as a carrier injection layer injecting electrons.

Meanwhile, in the light-emitting medium layer 110, it is possible to appropriately laminate carrier injection layers such as an electron transportation layer or a hole blocking layer (interlayer) between the negative electrodes and the light-emitting layer and an electron blocking layer (interlayer) between the positive electrode and the light-emitting layer as necessary.

A substrate wire for positive electrode extraction 104 and a substrate wire for negative electrode extraction 106 are provided outside the pixel areas a for connection with an external drive circuit. In the invention, a common element functions as the positive electrode 102 and the substrate wire for positive electrode extraction 104, and a common element functions as the negative electrode 105 and the substrate wire for negative electrode extraction 106 respectively for conveniently manufacturing the organic EL display panel, but the electrode and the substrate wire for electrode extraction may be hooked up with each other by providing a contact section, for example, a low-resistance external extraction electrode.

Furthermore, a transmittance-adjusting layer 107 is formed so as to cover almost the entire surface of an area that is inside a display region b and does not belong to the positive electrodes 102. The gap between the positive electrode 102 and the transmittance-adjusting layer 107 is preferably narrower, but it is necessary to electrically insulate the positive electrodes 102 from each other for independent light emission from adjacent pixels, and thus the gap is preferably equal to or thicker than the film thickness of the positive electrode 102, for example, 50 μm.

In FIG. 1, the transmittance-adjusting layer 107 is formed separately so as to prevent the contact with the first transparent electrodes 102 and the substrate wire for positive electrode extraction 104, and is formed in a comb shape. The presence of the transmittance-adjusting layer 107 provides uniform transmittance throughout the entire display area b, and favorable transparency can be obtained.

The hole injection layer 111 forms a pattern on the pixel areas a, but may cover the entire surface of the display area b. The hole injection layer covering the entire surface of the display area makes the film shape flat in the pixel areas, and enables the film thickness to be uniform in each pixel.

The hole transportation layer 112 forms a pattern only on the pixel areas a on the hole injection layer 111; however, similarly to the hole injection layer 111, the hole transportation layer may cover the entire surfaces of the pixel areas b.

It is possible to form the organic light-emitting layer 113 without causing colors to be mixed on the pixel areas a depending on the shape of the partition wall 103. In addition, the organic light-emitting layer may be formed between adjacent pixels as long as colors are not mixed. Furthermore, it is possible to produce an organic EL display panel by arraying the organic EL elements as pixels (sub-pixels). That is, it is possible to produce a full color organic EL display panel by, for example, separately coating the organic light-emitting layer 113 configuring the respective pixels with three colors of RGB without causing colors to be mixed.

The electron injection layer 114 is formed on the pixel areas a on the organic light-emitting layer 113, but may cover the entire surface of the display area b, and, furthermore, may have the same pattern as the second transparent electrode 105.

Next, each component of the organic EL display panel of the invention will be described in detail.

<Transparent Substrate>

Any material can be used for the transparent substrate as long as the material has transparency, mechanical strength and insulating properties, and is excellent in terms of dimensional stability. For example, it is possible to use a plastic film or sheet of glass, silica, polypropylene, polyether sulfone, polycarbonate, a cycloolefin polymer, polyarylate, polyamide, polymethyl methacrylate, polyethylene terephthalate or polyethylene naphthalate, or a transparent base material obtained by laminating a single layer or multiple layers of a metal oxide such as silicon oxide or aluminum oxide, a metal fluoride such as aluminum fluoride or magnesium fluoride, a metal nitride such as silicon nitride or aluminum nitride, a metal oxynitride such as silicon oxynitride, or a macromolecular resin film such as an acryl resin, an epoxy resin, a silicone resin or a polyester resin on the above-described plastic film or sheet.

In addition, to avoid the intrusion of moisture into the organic EL display panel, it is preferable to form an inorganic film, to apply a fluorine resin or to carry out damp proofing or a hydrophobic treatment. Particularly, to avoid the intrusion of moisture into the light-emitting medium layer, it is preferable to decrease the moisture content and gas transmittance coefficient of the substrate.

<First Transparent Electrode>

The first transparent electrodes 102 are formed on the transparent substrate, and patterning is carried out as necessary. In the invention, the first transparent electrodes are partitioned using the partition wall so as to correspond to the respective pixel areas a. As a material for the first transparent electrode, it is possible to use any of a single layer or a laminate of a transparent conductive polymer such as a polyaniline derivative, a polythiophene derivative, a polyvinyl carbazole (PVK) derivative or poly(3,4-ethylenedioxythiophene) (PEDOT), a metallic composite oxide such as indium tin composite oxide (ITO), indium zinc composite oxide or zinc aluminum composite oxide, or a fine particle-dispersed film obtained by dispersing fine particles of a metallic oxide or a metallic material including gold, platinum or the like in an epoxy resin, an acryl resin or the like.

In a case where the first transparent electrode is used as the positive electrode, a material having a high work function such as ITO is preferably selected. As a method for forming the first transparent electrode, it is possible to use a dry film-forming method such as a resistance heating deposition method, an electron beam deposition method, a reactive deposition method, an ion plating method or a sputtering method, a wet film-forming method such as a spin coating method, a typography method, a reverse printing method, a gravure printing method or a screen printing method, or the like depending on the material. As a patterning method for the pixel electrodes, it is possible to use an existing patterning method such as a mask deposition method, a photolithography method, a wet etching method or a dry etching method depending on the material or the film-forming method.

<Substrate Wire for Positive Electrode Extraction>

The substrate wire for positive electrode extraction is preferably made of the same material as that for the first transparent electrode for convenience; however, to maintain the display area b being transparent and to reduce the influence of the wire resistance, it is also possible to provide a contact section outside the pixel areas b and jointly provide a metallic material such as Cu or Al as an auxiliary electrode.

As a method for forming the substrate wire for positive electrode extraction, it is possible to use an existing patterning method such as a dry film-forming method such as a resistance heating deposition method, an electron beam deposition method, a reactive deposition method, an ion plating method or a sputtering method, a wet film-forming method such as a spin coating method, a typography method, a reverse printing method, a gravure printing method or a screen printing method, or the like depending on the material. As a patterning method for the substrate wire for positive electrode extraction, it is possible to use an existing patterning method such as a mask deposition method, a photolithography method, a wet etching method or a dry etching method depending on the material or the film-forming method.

<Transmittance-Adjusting Layer>

After forming the first transparent electrodes and the substrate wire for positive electrode extraction, the transmittance-adjusting layer 107 is formed. As a material for the transmittance-adjusting layer, it is possible to use any of a single layer or a laminate of a metallic composite oxide such as indium tin composite oxide (ITO), indium zinc composite oxide or zinc aluminum composite oxide, an inorganic compound such as SiN, SiNₓC_{y}, SiO, SiO₂ or LiF, a metallic oxide or a fine particle-dispersed film obtained by dispersing fine particles of a metallic material or a metal material including gold platinum or the like in an epoxy resin, an acryl resin or the like, but a material having the same refractive index as that of the first transparent electrode is preferably used, and the same material as that of the first transparent electrode is desirably used.

As a method for forming the transmittance-adjusting layer, it is possible to use a dry film-forming method such as a resistance heating deposition method, an electron beam deposition method, a reactive deposition method, an ion plating method or a sputtering method, a wet film-forming method such as a spin coating method, a typography method, a reverse printing method, a gravure printing method or a screen printing method, or the like depending on the material. As a patterning method for the transmittance-adjusting layer, it is possible to use an existing patterning method such as a mask deposition method, a photolithography method, a wet etching method or a dry etching method depending on the material or the film-forming method.

The first transparent electrodes, the substrate wire for positive electrode extraction and the transmittance-adjusting layer are preferably formed at the same time using the same material as for the first transparent electrode 102 to more conveniently obtain favorable transparency. That is, the first transparent electrodes, the substrate wire for positive electrode extraction and the transmittance-adjusting layer are preferably formed at the same time using an existing patterning method such as a mask deposition method, a photolithography method, a wet etching method or a dry etching method depending on the material or the film-forming method. When the first transparent electrodes, the substrate wire for positive electrode extraction and the transmittance-adjusting layer are formed at the same time, it is possible to simplify the manufacturing process, and to decrease the production cost.

In a case where the first transparent electrodes, the substrate wire for positive electrode extraction and the transmittance-adjusting layer are formed at the same time using the photolithography method, the first transparent electrodes, the substrate wire for positive electrode extraction and the transmittance-adjusting layer are formed by uniformly forming a transparent conductive material layer on the transparent substrate through deposition, sputtering, spin coating or the like, and then etching the transparent conductive material layer in the desired shapes of the first transparent electrodes, the substrate wire for positive electrode extraction and the transmittance-adjusting layer.

In a case where the first transparent electrodes, the substrate wire for positive electrode extraction and the transmittance-adjusting layer are formed at the same time using the mask deposition method, the first transparent electrodes, the substrate wire for positive electrode extraction and the transmittance-adjusting layer are formed by depositing a transparent conductive material on the transparent substrate using a mask that is a negative pattern of the desired shapes of the first transparent electrodes, the substrate wire for positive electrode extraction and the transmittance-adjusting layer.

In a case where the first transparent electrodes, the substrate wire for positive electrode extraction and the transmittance-adjusting layer are formed at the same time using the wet coating method, the first transparent electrodes, the substrate wire for positive electrode extraction and the transmittance-adjusting layer can be formed using a typography method, a reverse printing method, a gravure printing method or a screen printing method in which a sheet having the desired shapes of the first transparent electrodes, the substrate wire for positive electrode extraction and the transmittance-adjusting layer is used.

In a case where a plurality of pixel areas is provided and the transmittance-adjusting layer is made of a conductive material, it is necessary to form the first transparent electrodes and the transmittance-adjusting layer away from each other so that the first transparent electrodes and the transmittance-adjusting layer are electrically insulated from each other, but the gap between the first transparent electrodes and the transmittance-adjusting layer is preferably narrow to obtain uniform transmittance.

Particularly, since it is almost impossible to visually recognize the gap between the first transparent electrodes and the transmittance-adjusting layer of 50 μm or less, it is possible to obtain favorable transmittance uniformly throughout the entire surface. On the other hand, when the gap becomes less than 1 μm, it becomes difficult to maintain the first transparent electrodes and the transmittance-adjusting layer being electrically insulated in a case where the transmittance-adjusting layer is made of a conductive material. Therefore, the gap between the first transparent electrodes and the transmittance-adjusting layer is preferably in a range of 1 μm to 50 μm.

Particularly, in a case where the first transparent electrodes, the substrate wire for positive electrode extraction and the transmittance-adjusting layer, which are made of the same transparent conductive material, are formed at the same time using the photolithography method, the film thickness of the transparent conductive material to be patterned is thick, and the gap between the first transparent electrodes and the transmittance-adjusting layer is narrow, there is a huge concern that, during patterning using photolithography, the lower sections of the first transparent electrodes and the lower section of the transmittance-adjusting layer are brought into contact and electrically connected due to etching. Therefore, the gap between the first transparent electrodes and the transmittance-adjusting layer is preferably in a range of more than 20 μm and 50 μm or less to ensure the electric insulation therebetween.

Meanwhile, the gap between the first transparent electrodes and the transmittance-adjusting layer mentioned herein refers to the distance between an end section of the first transparent electrode and an end section of the transmittance-adjusting layer adjacent to the first transparent electrode on the same transparent substrate. In addition, in a case where the transmittance-adjusting layer is made of an insulating material, the first transparent electrodes and the transmittance-adjusting layer may be in contact with each other.

In the mask deposition method, the pattern may become dull depending on the mask size, the film-forming method such as sputtering and the film-forming conditions, a photolithography method, a wet etching method and a dry etching method are more preferable for high-precision pattern.

<Partition Wall>

The partition wall 103 of the invention is formed so as to partition the pixel areas a corresponding to the pixels. That is, the partition wall has an opening portion of the shape of an image being displayed.

The components and composition of a partition wall material will be described. A photosensitive composition for the partition wall of the invention (hereinafter, sometimes, referred to simply as “photosensitive composition”) contains at least (A) component: an ethylenic unsaturated compound, (B) component: a photopolymerization initiator and (C) component: an alkali-soluble binder. Generally, the photosensitive composition preferably further contains a surfactant or the like, and also contains a solvent.

Examples of a method for forming the partition wall include, similarly to that of the related art, a method in which an inorganic film is uniformly formed on a substrate, masked using a resist, and then dry-etched and a method in which a photosensitive resin is laminated on a substrate and patterned in a predetermined shape using a photolithography method.

The height of the partition wall is preferably in a range of 0.1 μm to 10 μm, and more preferably in a range of 0.5 μm to 2 μm. This is because, when the height is too high, the formation and sealing of the second transparent electrode is hindered and the transparency is decreased, and, when the height is too low, the end sections of the pixel electrodes are not fully covered or colors are mixed in adjacent pixels during the formation of the light-emitting medium layer.

<Hole Injection Layer>

Any material can be used to produce the hole injection layer 111, and the material preferably has a resistivity of 10⁴ Ω·cm or more to prevent short-circuit between pixels. In addition, unevenness may be given to the film thickness of the hole injection layer by providing the partition wall having a different-height shape, thereby suppressing short-circuiting between pixels. Examples of the material for the hole injection layer 111 include inorganic compounds containing one or more of transition metal oxides such as Cu₂O, Cr₂O₃, Mn₂O₃, FeOx, NiO, CoO, Pr₂O₃, Ag₂O, MoO₂, Bi₂O₃, ZnO, TiO₂, SnO₂, ThO₂, V₂O₅, Nb₂O₅, Ta₂O₅, MoO₃, WO₃ and MnO₂ and nitrides or sulfides thereof; or triarylamines such as polyaniline derivatives, oligoaniline derivatives, quinone diimine derivatives, polythiophene derivatives, polyvinyl carbazole (PVK) derivatives, poly(3,4-ethylenedioxythiophene) (PEDOT), pyrrol derivatives, aromatic amines, (triphenylamine) dimer derivatives (TPD), (α-naphtyl diphenylamine) dimer-(α-NPD) and [(triphenylamine) dimer]spirodimer (Spiro-TAD); starburst amines such as 4,4′,4″-tris[3-methylphenyl(phenyl)amino]triphenylamine(m-MTDATA) and 4,4′,4″-tris[1-naphtyl(phenyl)amino]triphenylamine(1-TNA TA); oligothiophenes such as 5,5′-α-bis-4{4-[bis(4-methylphenyl)amino]phenyl}-2,2′:5′,2′-α-terthiophene (BMA-3T); and organic materials such as aromatic amine-containing polymers, aromatic diamine-containing polymers, fluorine-containing aromatic amine polymers, triazole-based organic materials, oxazole-based organic materials, oxadiazole-based organic materials, silole-based organic materials and boron-based organic materials.

As a method for forming the hole injection layer 111, it is possible to use an existing film-forming method such as a dry film-forming method such as a resistance heating deposition method, an electron beam deposition method, a reactive deposition method, an ion plating method or a sputtering method, a wet film-forming method such as a spin coating method, a sol-gel method, an ink jet method, a nozzle printing method, a typography method, a slit coating method or a bar coating method depending on the material; however, in the invention, the method is not limited thereto, and an ordinary film-forming method can be used.

The film thickness of the hole injection layer 111 is preferably in a range of 20 nm to 100 nm. When the film thickness becomes smaller than 20 nm, short defects are likely to occur, and, when the film thickness becomes 100 nm or more, the current becomes low due to an increase in the resistance.

Inorganic materials are preferable since inorganic materials are generally excellent in heat resistance and electrochemical stability. Inorganic materials can be formed in a single layer or a laminate structure or layer mixture of a plurality of layers.

<Interlayer>

After the formation of the hole injection layer, it is possible to form the interlayer. In the present application, the hole transportation layer is formed in a line-shaped pattern on the hole injection layer formed throughout the entire surface, but the interlayer may be formed on the entire surface of the hole injection layer.

Examples of a material used for the interlayer include triarylamines such as polyaniline derivatives, oligoaniline derivatives, quinone diimine derivatives, polythiophene derivatives, polyvinyl carbazole (PVK) derivatives, poly(3,4-ethylenedioxythiophene) (PEDOT), pyrrol derivatives, aromatic amines, (triphenylamine) dimer derivatives (TPD), (α-naphtyl diphenylamine) dimer-(α-NPD) and [(triphenylamine)dimer]spirodimer (Spiro-TAD); starburst amines such as 4,4′,4″-tris[3-methylphenyl(phenyl)amino]triphenylamine(m-MTDATA) and 4,4′,4″-tris[1-naphtyl(phenyl)amino]triphenylamine (1-TNA TA); oligothiophenes such as 5,5′-α-bis-4{4-[bis(4-methylphenyl)amino]phenyl}-2,2′:5′,2′-α-terthiophene(BMA-3T); and organic materials such as aromatic amine-containing polymers, aromatic diamine-containing polymers, fluorine-containing aromatic amine polymers, triazole-based organic materials, oxazole-based organic materials, oxadiazole-based organic materials, silole-based organic materials and boron-based organic materials.

As a method for forming the interlayer 112, it is possible to use an existing film-forming method such as a dry film-forming method such as a resistance heating deposition method, an electron beam deposition method, a reactive deposition method, an ion plating method or a sputtering method, a wet film-forming method such as a spin coating method, a sol-gel method, an ink jet method, a nozzle printing method, a typography method, a slit coating method or a bar coating method depending on the material; however, in the invention, the method is not limited thereto, and an ordinary film-forming method can be used.

<Organic Light-Emitting Layer>

After the formation of the hole transportation layer 112, the organic light-emitting layer 113 is formed. The organic light-emitting layer is a layer that emits light using the recombination of holes and electrons, and, while the organic light-emitting layer is formed so as to coat the interlayer 112 in a case where the display light emitted from the organic light-emitting layer 113 is monochromatic, but the organic light-emitting layer can be more preferably used when patterned as necessary to obtained multicolor display light.

Examples of an organic light-emitting material forming the organic light-emitting layer 113 include materials obtained by dispersing a light-emitting colorant such as a coumarin-based colorant, a perylene-based colorant, a pyran-based colorant, an anthrone-based colorant, a porphyrin-based colorant, a quinacridone-based colorant, an N,N′-dialkyl-substituted quinacridone-based colorant, a naphthalimide-based colorant, an N,N′-diaryl-substituted pyrrolopyrrole-based colorant or an iridium complex-based colorant in a polymer such as polystyrene, polymethyl methacrylate or polyvinyl carbazole; and macromolecular materials such as polyarylene-based macromolecular materials, polyarylene vinylene-based macromolecular materials and polyfluorene-based macromolecular materials; however, in the invention, the organic light-emitting material is not limited thereto.

The organic light-emitting material is dissolved or stably dispersed in a solvent so as to produce organic light-emitting ink. Examples of the solvent dissolving or dispersing the organic light-emitting material include toluene, xylene, acetone, anisole, methyl ethyl ketone, methyl isobutyl ketone, cyclohexanone and solvent mixtures thereof. Among the above-described materials, aromatic organic solvents such as toluene, xylene and anisole are preferable in terms of the solubility in the organic light-emitting material. In addition, a surfactant, an antioxidant, a viscosity adjuster, an ultraviolet absorbent and the like may be added to the organic light-emitting ink as necessary.

In addition to the above-described macromolecular materials, it is possible to use low-molecular light-emitting materials such as 9,10-diarylanthracene derivatives, pyrene, coronene, perylene, rubrene, 1,1,4,4-tetraphenylbutadiene, tris(8-quinolato)aluminum complexes, tris(4-methyl-8-quinolato)aluminum complexes, bis(8-quinolato)zinc complexes, tris(4-methyl-5-trifluoromethyl-8-quinolinato)aluminum complexes, tris(4-methyl-5-cyan-8-quinolato)aluminum complexes, bis(2-methyl-5-trifluoromethyl-8-quinolato)[4-(4-cyanophenyl)phenolate]aluminum complexes, bis(2-methyl-5-cyano-8-quinolinato) [4-(4-cyanophenyl)phenolate]aluminum complexes, tris(8-quinolinato)scandium complexes, bis(8-(paratosyl)aminoquinoline)zinc complexes, cadmium complexes, 1,2,3,4-tetraphenylcyclopentadiene and poly-2,5-diheptyloxy-paraphenylene vinylene.

As a method for forming the organic light-emitting layer 113, it is possible to use an existing film-forming method such as a wet film-forming method such as an ink jet printing method, a nozzle printing method, a typography method, a gravure printing method, a screen printing method, a slit coating method or a bar coating method, and, in the invention, the method is not limited thereto, and, particularly, in a case where the light-emitting layer is coated into individual light-emitting colors using the organic light-emitting ink obtained by dissolving or stably dispersing the organic light-emitting material in the solvent, the ink jet method, the nozzle printing method and the typography method are preferred since the light-emitting layer can be patterned by transferring the ink between the partition walls.

<Method for Forming the Light-Emitting Medium Layer>

A case where the light-emitting medium layer is formed using the typography method will be described below.

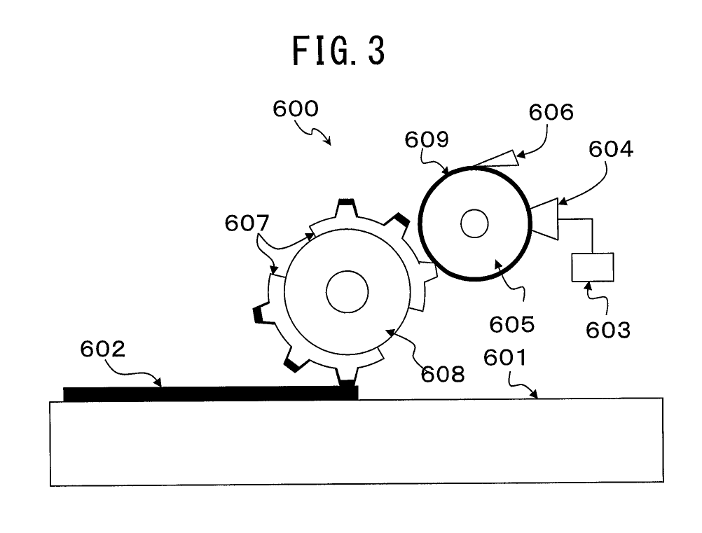

FIG. 3 illustrates a schematic view of a typography apparatus 600 that prints a pattern on a substrate to be printed 602 on which the pixel electrodes, the hole injection layer and the hole transportation layer are formed using the organic light-emitting ink made of the organic light-emitting material. The manufacturing apparatus includes an ink tank 603, an ink chamber 604, an anilox roll 605 and a sheet core 608 on which a plate 607 provided with relief printing plates is mounted. The organic light-emitting ink diluted using a solvent is stored in the ink tank 603, and the organic light-emitting ink is sent to the ink chamber 604 from the ink tank. The anilox roll 605 is rotatably supported in contact with an ink supply section in the ink chamber 604.

In response to the rotation of the anilox roll 605, an ink layer 609 of the organic light-emitting ink supplied to a surface of the anilox roll is formed into a uniform film thickness. The ink in the ink layer is transferred to the relief printing plates on the plate 607 mounted on the sheet core 608 driven to rotate near the anilox roll. The substrate to be printed 602 is installed on a stage 601, the ink present on protrusions on the plate 607 is printed on the substrate to be printed 602, and an organic light-emitting layer is formed on the substrate to be printed through a drying process as necessary.

Other light-emitting medium layers can also be formed using the above-described forming method in the same manner in a case where the light-emitting medium layers are coated with the ink.

<Electron Injection Layer>

After the formation of the organic light-emitting layer 113, it is possible to form the electron injection layer 114. The layer can be formed using a vacuum deposition method and a low-molecular material such as a triazole-based material, an oxazole-based material, an oxadiazole-based material, a silole-based material or a boron-based material, a salt or oxide of an alkali metal or an alkali earth metal such as lithium fluoride, lithium oxide or sodium fluoride, or the like as a material for the electron injection layer.

<Second Transparent Electrode>

Next, the second transparent electrode 105 is formed. The same material and the same forming method as for the first transparent electrodes are used for the second transparent electrode; however, in a case where the second transparent electrode is used as a negative electrode, a substance having a high electron injection efficiency into the light-emitting layer 113 and a low work function is jointly used. Specifically, a single metallic body of Mg, Al, Yb or the like may be used, or Al or Cu having high stability and high conductivity may be laminated with an approximately 1 nm-thick film of Li or a Li compound such as a Li₂O or LiF sandwiched in the interface in contact with the light-emitting medium layer. Alternatively, an alloy of one or more metal elements having a low work function such as Li, Mg, Ca, Sr, La, Ce, Er, Eu, Sc, Y or Yb and a stable metal element such as Ag, Al or Cu may be used to satisfy both electron injection efficiency and stability. Specifically, it is possible to use an alloy such as MgAg, AlLi or CuLi; however, to obtain transparency, it is necessary to form an extremely thin film as thin as 10 nm or less.

While it is possible to make the organic EL display panel emit light by sandwiching the light-emitting material between the electrodes and flowing a current, since the organic light-emitting material easily deteriorates due to moisture or oxygen in the atmosphere, it is normal to provide a protective layer 108 or a sealing body 109 to shield the second transparent electrode from outside.

<Protective Layer>

Any material can be used for the protective layer 108 as long as the material has favorable barrier properties such as low permeability with respect to moisture or oxygen in the atmosphere, high transmittance and high transparency, and examples thereof include silicon oxide (SiO₂), silicon nitride (SiN), silicon oxynitride (SiON) and the like. Among the above-described materials, carbon-containing silicon nitride (SiNxCy) is particularly preferred, and, in a case where carbon-containing silicon nitride is used, a film that continuously changes the carbon amount in the protective layer is used. With a change in the carbon amount, softness, excellent coverage and excellent adhesion can be obtained in a film section having a large carbon content, and a high density and favorable barrier properties can be obtained in a film section having a small carbon content. Regarding the carbon amount, the ratio of the carbon amount to the Si amount, which is set to one, is desirably less than 1.0. This is because, when the ratio of the carbon amount becomes 1.0 or more, the film may be colored or become brittle. It is preferable to laminate a plurality of layers having a changing composition. Laminating a plurality of layers can cover protrusions that cannot be covered with a single layer, and an effect that alleviates cracks generated in the first layer is expected, thereby producing a film having more favorable barrier properties.

A preferred embodiment of the invention preferably includes a layer in which the amounts of nitrogen and carbon contained in the carbon-containing silicon nitride (SiNxCy) configuring the protective layer satisfy ranges of 1.0≦x≦1.4 and 0.2≦y≦0.4 and a layer in which the amounts of nitrogen and carbon contained satisfy ranges of 0.4≦x<1.0 and 0.4<y<1.0.

With the above-described embodiment, it is possible to satisfy stress relaxation properties, attachment to the substrate surface and favorable gas barrier characteristics, and to improve the protection characteristics of the element. When forming the carbon-containing silicon nitride (SiNxCy), a plasma CVD method is used. In the plasma CVD method, since all reactions that produce films are caused in a gaseous phase, it is not necessary to cause the reaction on the substrate surface, and thus the plasma CVD method is the most suitable film-producing method for producing films at a low temperature.

Examples of the method for continuously changing the carbon amount in the protective layer include a method in which an organic silicon compound, either or both of ammonia and nitrogen, and hydrogen are used as raw materials, and the plasma CVD method is carried out. The carbon amount in the film can be decreased by, for example, intensifying power being applied.

In addition, the examples include a method in which silane, either or both of ammonia and nitrogen, hydrogen and carbon-containing gas are used as raw material gases, and the plasma CVD method is carried out while changing the concentration of the carbon-containing gas. In this case, the composition can be controlled by changing the flow rate of the carbon-containing gas during film production. In addition, it is desirable to appropriately adjust the composition using parameters such as film production substrate temperature and gas pressure.

Examples of the above-described organic silicon compound include trisdimethylaminosilane (TDMAS), hexamethyldisilazane (HMDS), hexamethyldisiloxane (HMDSO), tetramethyldisilazane (TMDS) and the like. In addition, examples of the above-described carbon-containing gas include methane, ethylene, propene and the like.

The thicknesses of the respective layers in the protective layer 108 are not limited, but are desirably in a range of approximately 100 nm to 500 nm, and the total thickness preferably remains at approximately 1000 nm. Within the above-described range, it is possible to cover defects such as pinholes in the film, and the barrier properties against the intrusion of oxygen and moisture are significantly improved. Furthermore, it is possible to produce the film within a short period of time, and light extraction from the organic light-emitting layer 113 is not hindered. In addition, when a large content of carbon is given on a negative electrode 105 side and the content is changed to decrease as the distance from the negative electrode 105 increases, additional improvement in adhesion and coatabilty is expected.

<Sealing Body>

Next, the sealing body 109 is adhered to the top of the protective layer 108. The adhesion of the sealing body can further improve the barrier properties and provide resistance against mechanical damage that cannot be covered only with the above-described protective layer 108. In addition, it is also possible to provide, for example, a resin layer on the sealing body.

The sealing body needs to be made of a base material having low permeability with respect to moisture or oxygen. In addition, examples of the material include ceramics such as alumina, silicon nitride and boron nitride, glass such as alkali-free glass and alkali glass, silica, moisture-resistant films and the like. Examples of the moisture-resistant film include films obtained by forming SiOx on both surfaces of a plastic base material using a CVD method, films having low permeability, water-absorbing films, polymer films coated with a water absorbent, and the like, and the water vapor permeability of the moisture-resistant film is preferably 10⁻⁶ g/m²/day or less.

When adhering the sealing body 109, an adhesive may be uniformly applied to a sealing body 109 side, or may be applied so as to surround the periphery. In addition, a method in which an adhesive layer formed in a sheet shape is thermally transferred may be employed. As a material for the adhesion layer, it is possible to use a single layer or a laminate of a photo-curable adhesive resin, thermosetting adhesive resin or two-component curable adhesive resin that is made of an epoxy-based resin, an acryl-based resin, a silicone-based resin or the like; a thermoplastic adhesive resin made of an acid denature such as polyethylene or polypropylene; or the like. Particularly, an epoxy-based thermosetting adhesive resin which has excellent moisture resistance and excellent water resistance and does not significantly contract during curing is desirably used. In addition, a drying agent such as barium oxide or calcium oxide may be incorporated to remove moisture contained in the adhesive layer to an extent that the light permeation of the adhesive layer is not hindered, or approximately several percent of an inorganic filler may be incorporated to control the thickness of the adhesive layer.

The adhesive-attached sealing body 109 produced in the above-described manner is adhered, and a curing treatment is carried out respectively. It is desirable to carry out the above-described series of protective layer-forming process in a nitrogen atmosphere, but carrying out the above-described process in the atmosphere does not make huge difference as long as the process is carried out for a short period of time after the production of the protective layer 108.

Examples of a material for the resin layer on the sealing body include photo-curable adhesive resins, thermosetting adhesive resins and two-component curable adhesive resins that are made of an epoxy-based resin, an acryl-based resin, a silicone-based resin or the like; acryl-based resins such as ethylene ethyl acrylate (EEA) polymers; vinyl-based resins such as ethylene vinyl acetate (EVA); thermoplastic resins such as polyamide and synthetic rubber; and thermoplastic adhesive resins such as acid denatures of polyethylene or polypropylene. Examples of a method for forming the resin layer on the sealing body include a solvent solution method, an extraction and lamination method, a melting and hot melting method, a calendar method, a nozzle application method, a screen printing method, a vacuum laminating method, a hot roller laminating method and the like. It is also possible to contain a moisture-absorbing and oxygen-absorbing material as necessary. The thickness of the resin layer formed on the sealing body is arbitrarily determined depending on the size or shape of an organic EL display panel to be sealed, but is desirably in a range of approximately 5 μm to 500 μm. Meanwhile, the resin layer is formed on the sealing body in the present case, but it is also possible to form the resin layer directly on an organic EL display panel side.

### EXAMPLES

### Example 1

Hereinafter, examples of the invention will be described.

An alkali-free glass sheet OA-10 manufactured by Nippon Electric Glass Co., Ltd. was prepared as a transparent substrate. The substrate had a 200 mm×200 mm size, a 5 inch-long diagonal, and a display section in the center.

The substrate was installed in a sputtering apparatus for film formation in which indium tin oxide (ITO) was installed, and an indium tin oxide film was formed on the entire surface so as to obtain a thickness of 50 nm.

Next, a TFR790PL positive resist manufactured by Nippon Ohka was formed on the entire surface of the substrate using a spin coater at a thickness of 2 μm, and then wet-etched using a second aqueous solution of ferric chloride through photolithography except for positive electrodes, a positive electrode extraction wire and a transmittance-adjusting layer, thereby forming the positive electrodes, the positive electrode extraction wire and the transmittance-adjusting layer. Meanwhile, the distance between the positive electrodes and the positive electrode extraction wire and between the positive electrodes and the transmittance-adjusting layer were set to 5 μm.

Next, an acryl-based transparent positive resist manufactured by Zeon Corporation was formed on the entire surface of the substrate using a spin coater at a thickness of 1 μm, and then a partition wall was formed through photolithography. Therefore, pixel areas and positive electrode contact sections were partitioned.

After that, the substrate was set in a printing machine, and an ink obtained by dissolving a polyfluorene derivative, which was a hole injection material, in anisole so as to obtain a concentration of 1.0% was printed on pixel sections sandwiched between the partition walls using the typography method in accordance with a line pattern for a hole injection layer. At this time, an anilox roll having 300 lines per inch and a photosensitive resin sheet were used. The film thickness of the hole injection layer reached 40 nm after the printing and drying.

After that, the substrate was set in the printing machine, and an ink obtained by dissolving a polyvinyl carbazole derivative, which was an interlayer material, in toluene so as to obtain a concentration of 0.5% was printed on pixel electrodes sandwiched between insulating layers using the typography method in accordance with a line pattern for the interlayer. At this time, an anilox roll having 300 lines per inch and a photosensitive resin sheet were used. The film thickness of the interlayer reached 20 nm after the printing and drying.

Next, the substrate was set in the printing machine, and an organic light-emitting ink obtained by dissolving a polyphenylene vinylene derivative, which was an organic light-emitting material, in toluene so as to obtain a concentration of 1% was printed on the pixel electrodes sandwiched between the insulating layers using the typography method in accordance with a line pattern for an organic light-emitting layer. At this time, an anilox roll having 150 lines per inch and a photosensitive resin sheet corresponding to the pitches of the pixels were used. The film thickness of an organic light-emitting layer reached 80 nm after the printing and drying. The above-described process was repeated a total of three times, and organic light-emitting layers corresponding to light emission colors of red (R), yellow (Y), green (G), blue (B) and white (W) were formed in the respective pixels.

After that, a Ba film was formed at a thickness of 4 nm as an electron injection layer using the vacuum deposition method and a shadow mask so as to cover the entire display section.

After that, a pattern of a 100 nm-thick ITO film was formed as a negative electrode using a metal mask through facing target sputtering (FTS).

After that, a SiNxCy protective layer was formed. As the protective layer, a carbon-containing silicon nitride film having a gradient composition was produced using methane, monosilane, nitrogen gas and hydrogen gas as raw material gases through the plasma CVD method. Specifically, the element was transported in a nitrogen atmosphere, and then moved to a plasma DVD apparatus. After a vacuum chamber was depressurized to 10⁻² Pa or less, silane, nitrogen, methane and hydrogen were introduced as raw material gases, and plasma was generated at a high frequency (13.56 MHz). The flow rate of the methane gas was decreased along with a change in the deposition time so as to make the composition gradient, the flow rate of the methane gas was set to zero, and then the initial amount of the methane gas was introduced, thereby forming a layer structure. The above-described layer had a film thickness of 300 nm, and, since the above-described process was repeated three times, the thickness of the protective layer reached 900 nm.

After that, a sealed glass substrate in which a thermosetting resin had been applied onto the entire surface of the above-described protective layer as a sealing body using a die coater was adhered to an element substrate using a thermal roller laminator at a temperature of 100° C. After the adhesion, the sealed glass substrate was further cured at 100° C. for one hour.

An organic EL display panel obtained in the above-described manner had favorable light-emitting characteristics, and also normally operated.

In addition, as a result of measuring the transmittance at individual points in a display area while light was not emitted using a microspectroscopic transmittance measurement apparatus manufactured by Otsuka Electronics Co., Ltd., the transmittance at a wavelength of 550 nm in a pixel area was 65%, and the transmittance outside the pixels, that is, on the transmittance-adjusting layer, was 70%. Uniform transmittance was obtained throughout the entire surface, and the transparency was favorable.

### Example 2

After ITO was formed on the entire surface of a transparent substrate using the same method as in Example 1, a TFR790PL positive resist manufactured by Nippon Ohka was formed on the entire surface of the substrate using a spin coater at a thickness of 2 μm, and wet-etched using an aqueous solution of ferric chloride through photolithography except for positive electrodes and a positive electrode extraction wire, thereby forming the positive electrodes and the positive electrode extraction wire.

After that, SiN was formed on the entire surface using the plasma CVD method so as to obtain a film thickness of 50 nm, and a transmittance-adjusting layer made of SiN was formed in a pattern using the photolithography method and dry etching in the same manner as described above.

Hereinafter, an organic EL display panel was produced in the same manner as in Example 1.

The organic EL display panel obtained in the above-described manner obtained favorable light-emitting characteristics, and also normally operated.

In addition, as a result of measuring the transmittance while light was not emitted using the same method as in Example 1, the transmittance at a wavelength of 550 nm in a pixel area was 65%, and the transmittance outside the pixels, that is, on the transmittance-adjusting layer, was 70% so that uniform transmittance was obtained throughout the entire surface, and the transparency was favorable.

### Comparative Example 1

An organic EL display panel was produced in the same manner as in Example 1 except for the fact that the transmittance-adjusting layer was not formed in Example 1.

The organic EL display panel obtained in the above-described manner obtained favorable light-emitting characteristics, and also normally operated.

However, as a result of measuring the transmittance while light was not emitted using the same method as in Example 1, the transmittance at a wavelength of 550 nm in a pixel area was 65%, and the transmittance outside the pixels, that is, on the transmittance-adjusting layer, was 80% such that the positive electrode pattern could be recognized and were not uniform, and the transparency was poor.

The above-described results are summarized in Table 1.

TABLE 1

| | | | | | Recognition of | |
|---|---|---|---|---|---|---|
| | Transmittance- | | Transmittance | Transmittance | positive | |
| | adjusting | Characteristics | in pixel | outside | electrode | |
| | layer | operation | area | pixels | pattern | Transparency |
| Ex. 1 | ITO | Favorable | 65% | 70& | No | Favorable |
| Ex. 2 | SiN | Favorable | 65% | 70& | No | Favorable |
| Comp. | N/A | Favorable | 65% | 80% | Yes | Poor |
| Ex. 1 | | | | | | |

### REFERENCE SIGNS LIST

101 transparent substrate
102 first transparent electrode (positive electrode)
103 partition wall
104 substrate wire for positive electrode extraction
105 second transparent electrode (negative electrode)
106 substrate wire for negative electrode extraction
107 transmittance-adjusting layer
108 protective layer
109 sealing body
110 organic light-emitting medium layer
111 hole injection layer
112 interlayer
113 organic light-emitting layer
114 electron injection layer
a pixel area
b display area
600 typography apparatus
601 stage
602 substrate to be printed
603 ink tank
604 ink chamber
605 anilox roll
606 doctor blade
607 relief printing plate
608 sheet core
609 ink layer

1. A transparent organic electroluminescence display panel comprising:
first transparent electrodes formed on a transparent substrate;
a transmittance-adjusting layer formed on the transparent substrate and apart from the first transparent electrodes;
a partition wall formed on the transparent substrate and the transmittance-adjusting layer so as to partition the first transparent electrodes;
a light-emitting medium layer formed on the first transparent electrodes and including at least an organic light-emitting layer; and
a second transparent electrode formed on the light-emitting medium layer.

2. The transparent organic electroluminescence display panel according to claim 1, wherein the transmittance-adjusting layer is made of the same material as materials of the first transparent electrodes.

3. The transparent organic electroluminescence display panel according to claim 1, wherein the first transparent electrodes and the transmittance-adjusting layer are formed apart from each other, a gap between the first transparent electrode and the transmittance-adjusting layer is in a range of 1 μm to 50 μm.

4. A manufacturing method for the transparent organic electroluminescence display panel according to claim 1, wherein the first transparent electrodes and the transmittance-adjusting layer are formed at the same time.
